(19) United States
(12) Patent Application Publication
(10) Pub. No.: US 2023/0011303 A1
(43) Pub. Date: Jan. 12, 2023

(54) CLOSE COUPLE DIFFUSER FOR PHYSICAL VAPOR DEPOSITION WEB COATING

(71) Applicant: Applied Materials, Inc., Santa Clara, CA (US)

(72) Inventors: David Masayuki ISHIKAWA, Mountain View, CA (US); Sumedh Dattatraya ACHARYA, Bangalore (IN); Visweswaren SIVARAMAKRISHNAN, Cupertino, CA (US)

(21) Appl. No.: 17/825,136

(22) Filed: May 26, 2022

Related U.S. Application Data
(60) Provisional application No. 63/219,928, filed on Jul. 9, 2021.

(51) Int. Cl. C23C 14/56; C23C 14/24; C23C 14/50

(52) U.S. Cl. CPC C23C 14/562; C23C 14/243; C23C 14/50

(57) ABSTRACT

An evaporation system for providing a gas for a reactive deposition process, reactive deposition apparatuses, and methods of reactive deposition are provided. The evaporation system in includes a multi-zone diffuser assembly for single or double-sided continuous roll-to-roll or batch coating of web substrates. The diffuser assembly is sized to accommodate at least a portion of a coating drum. The diffuser assembly includes a plurality of interchangeable solid plates and diffuser plates for delivering an evaporated material toward a web substrate. The diffuser plates are fluidly coupled with an evaporation source.

### CROSS-REFERENCES TO RELATED APPLICATIONS

This application claims benefit of and priority to U.S. Provisional patent application Ser. No. 63/219,928, filed on Jul. 9, 2021, which is incorporated herein by reference in its entirety,

### BACKGROUND

### Field

The present disclosure generally relates to an evaporation system for providing a gas for a reactive deposition process, reactive deposition apparatuses, and methods of reactive deposition. More particularly, the present disclosure generally relates to a multi-zone diffuser for single or double-sided continuous roll-to-roll or batch coating of web substrates.

### Description of the Related Art

Processing of flexible substrates, such as plastic films or foils, is in high demand in the packaging industry, semiconductor industries and other industries. Processing may include coating of a flexible substrate with a chosen material, such as a metal. The economical production of these coatings is frequently limited by the thickness uniformity necessary for the product, the reactivity of the coating material, the cost of the coating material, and the deposition rate of the coating material. The most demanding applications generally involve deposition in a vacuum chamber for precise control of the coating thickness. The high capital cost of vacuum coating equipment necessitates a high throughput of coated area for large-scale commercial applications. The coated area per unit time is typically proportional to the coated substrate width and the vacuum deposition rate of the coating material.

A process that can utilize a large vacuum chamber has tremendous economic advantages. Vacuum coating chambers, substrate treating and handling equipment, and pumping capacity, increase in cost less than linearly with chamber size; therefore, the most economical process for a fixed deposition rate and coating design will utilize the largest substrate available. A larger substrate can generally be fabricated and divided into discrete parts after the coating process is complete. In the case of products manufactured from a continuous web, the web is slit or sheet cut to either a final product dimension or a narrower web suitable for the subsequent manufacturing operations.

One technique used in reactive deposition in vacuum chambers is thermal evaporation. Thermal evaporation readily takes place when a source material is heated in an open crucible to a temperature where there is a sufficient vapor flux from the source for condensation on a cooler substrate. The source material can be heated indirectly by heating the crucible, or directly by a high current electron beam directed into the source material confined by the crucible. Thermal evaporation typically takes place at high temperatures. Web handling systems are typically not capable of double-sided coating let alone safe thermal evaporation of metallic materials such as, for example, lithium.

Thus, there is a need for methods and systems that can meet volume manufacturing objectives for device performance, yield, safety, throughput, and cost.

### SUMMARY

The present disclosure generally relates to an evaporation system for providing a gas for a reactive deposition process, reactive deposition apparatuses, and methods of reactive deposition. More particularly, the present disclosure generally relates to a multi-zone diffuser for single or double-sided continuous roll-to-roll or batch coating of web substrates.

In one aspect, a diffuser assembly is provided. The diffuser assembly includes a first semicircular sidewall having a first top surface and a first arcuate surface extending from a first end of the first top surface to a second end of the first top surface. The diffuser assembly further includes a second semicircular sidewall opposing the first semicircular sidewall and having a second top surface and a second arcuate surface extending from a first end of the second top surface to a second end of the second top surface. The diffuser assembly further includes a plurality of linear rails extending from the first arcuate surface of the first semicircular sidewall to the second arcuate surface of the second semicircular sidewall, wherein each linear rail is positioned parallel to an adjacent linear rail. The diffuser assembly further includes a plurality of plates extending from a first linear rail to a second linear rail of the plurality of linear rails, wherein the plurality of plates define at least a portion of a circumferential surface extending from a first end of the first top surface to a second end of the first top surface and at least one of the plates is a first diffuser plate having a plurality of discharge openings for delivering an evaporated material.

In another aspect, an evaporation assembly is provided. The evaporation assembly includes a diffuser assembly. The diffuser assembly includes a first semicircular sidewall having a first top surface and a first arcuate surface extending from a first end of the first top surface to a second end of the first top surface. The diffuser assembly further includes a second semicircular sidewall opposing the first semicircular sidewall and having a second top surface and a second arcuate surface extending from a first end of the second top surface to a second end of the second top surface. The diffuser assembly further includes a plurality of linear rails extending from the first arcuate surface of the first semicircular sidewall to the second arcuate surface of the second semicircular sidewall, wherein each linear rail is positioned parallel to an adjacent linear rail. The diffuser assembly further includes a plurality of plates extending from a first linear rail to a second linear rail of the plurality of linear rails, wherein the plurality of plates define at least a portion of a circumferential surface extending from a first end of the first top surface to a second end of the first top surface and at least one of the plates is a first diffuser plate having a plurality of discharge openings operable to deliver an evaporated material. The evaporation assembly further includes a crucible fluidly coupled with the first diffuser plate and operable to hold a material to be evaporated.

In yet another aspect, a system for reactive deposition is provided. The reactive systems includes a coating drum having a deposition surface over which a continuous flexible substrate travels while evaporated material is deposited onto the continuous flexible substrate. The system further includes a diffuser assembly. The diffuser assembly includes a first semicircular sidewall having a first top surface and a first arcuate surface extending from a first end of the first top surface to a second end of the first top surface. The diffuser assembly further includes a second semicircular sidewall opposing the first semicircular sidewall and having a second top surface and a second arcuate surface extending from a first end of the second top surface to a second end of the second top surface. The diffuser assembly further includes a plurality of linear rails extending from the first arcuate surface of the first semicircular sidewall to the second arcuate surface of the second semicircular sidewall, wherein each linear rail is positioned parallel to an adjacent linear rail. The diffuser assembly further includes a plurality of plates extending from a first linear rail to a second linear rail of the plurality of linear rails. The plurality of plates define at least a portion of a circumferential surface extending from a first end of the first top surface to a second end of the first top surface. At least one of the plates is a first diffuser plate having a plurality of discharge openings operable to deliver the evaporated material to the continuous flexible substrate. The first semicircular sidewall, the second semicircular sidewall, and the circumferential surface define a volume sized to accommodate a portion of the coating drum. The system further includes a crucible fluidly coupled with the first diffuser plate and operable to hold a material, which is heated to form the evaporated material.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the implementations, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a schematic side view of an evaporation apparatus having an evaporation assembly according to one or more implementations of the present disclosure.

FIG. 2 illustrates a perspective view of a diffuser assembly according to one or more implementations of the present disclosure.

FIG. 3 illustrates a perspective view of the diffuser assembly of FIG. 2 according to one or more implementations of the present disclosure.

FIG. 4 illustrates an enlarged perspective view of a portion of the diffuser assembly of FIG. 3 according to one or more implementations of the present disclosure.

FIG. 5 illustrates a schematic cross-sectional view of a thermal evaporator according to one or more implementations of the present disclosure.

FIG. 6 illustrates a perspective view of the thermal evaporator of FIG. 5 according to one or more implementations of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Reference will now be made in detail to the various implementations of the present disclosure, one or more examples of which are illustrated in the figures. Within the following description of the drawings, the same reference numbers refer to the same components. Generally, only the differences with respect to individual implementations are described. Each example is provided by way of explanation of the present disclosure and is not meant as a limitation of the present disclosure. Further, features illustrated or described as part of one implementation can be used on or in conjunction with other implementations to yield yet a further implementation. It is intended that the description includes such modifications and variations.

Many of the details, dimensions, angles and other features shown in the Figures are merely illustrative of particular implementations. Accordingly, other implementations can have other details, components, dimensions, angles and features without departing from the spirit or scope of the present disclosure. In addition, further implementations of the disclosure can be practiced without several of the details described below.

According to some implementations, evaporation processes and evaporation apparatus for layer deposition on substrates, for example on flexible substrates, are provided. Thus, flexible substrates can be considered to include among other things films, foils, webs, strips of plastic material, metal or other materials. Typically, the terms “web,” “foil,” “strip,” “substrate” and the like are used synonymously. According to some implementations, components for evaporation processes, apparatuses for evaporation processes and evaporation processes according to implementations described herein can be provided for the above-described flexible substrates. However, they can also be provided in conjunction with non-flexible substrates such as glass substrates or the like, which are subject to the reactive deposition process from evaporation sources.

Energy storage devices, for example, Li-ion batteries, typically include a positive electrode (e.g., cathode) and a negative electrode separated by a polymer separator with a liquid electrolyte. Solid-state batteries also typically include a positive electrode (e.g., cathode) and a negative electrode (e.g., anode) but replace both the polymer separator and the liquid electrolyte with an ion-conducting material. The anode can be manufactured using graphite powders one to ten microns in diameter held together with five percent by weight polymer binders and compressed to about thirty percent porosity and twenty to one hundred microns, for example, fifty to eighty microns, thickness on both sides of an eight to eighteen microns thick copper foil. The anode can be a lithium metal anode.

The specific energy and energy density of lithium-based energy storage devices appreciably declines due to active lithium loss during the first cycle charge when five to twenty percent of the lithium from the cathode is consumed by solid electrolyte interphase (“SEI”) formation at the anode.

Anode prelithiation prior to the first cycle charge is a common strategy for compensating for active lithium loss. In addition, prelithiation provides other performance and reliability advantages to lithium-based energy storage device. For example, prelithiation can decrease lithium-based energy storage device impedance thus improving rate capability. Further, for silicon (Si)-based anodes, prelithiation can mitigate silicon cracking and pulverization by pre-expanding the silicon to enhance anode mechanical stability.

Various anode prelithiation methods exist. These prelithiation methods include, for example, chemical prelithiation, electrochemical prelithiation, prelithiation by direct contact to lithium metal, and stabilized lithium metal powder (“SLMP”). These prelithiation methods share common volume lithium-based energy storage device manufacturing disadvantages, such as, long reaction times and inherent safety risks, which are unsuitable for volume lithium-based energy storage device manufacture.

SLMP, with up to 30% of the Li₂CO₃ powder shells typically remaining uncracked, incorporates inactive material to the cell mass, which reduces the energy density of the energy storage device. Loose powder particles liberated during spreading are dislodged within the electrolyte during use and are inherent safety and reliability risks. Electrochemical prelithiation produces reactive material in ambient air, which can increase cell impedance due to nitrogen and oxygen contamination. Direct contact to lithium metal is a non-uniform and low yield process hindered by thin lithium metal foils sixty centimeters wide and discontinuous at twenty meters long or shorter. In addition, except for electrochemical prelithiation, energy storage devices manufactured using these prelithiation methods may not perform as well as energy storage devices pre-lithiated with methods involving reactive lithium ions. Reactive lithium ions are more effective than lithium metal because the ions can penetrate and intercalate electrode pores to form lithium alloys throughout the graphite composite.

Vacuum web coating for anode prelithiation and solid metal anode protection involves thick (three to twenty micron) metallic (e.g., lithium) deposition on double-side-coated and calendered alloy-type graphite anodes and current collectors, for example, six micron or thicker copper foil, nickel foil, or metallized plastic web. One technique for deposition is thermal evaporation. Thermal evaporation is understood to facilitate high quality and controllable prelithiation, however strategies using this approach historically were cost prohibitive due to capital, energy, and maintenance costs. Commercial demand for advanced electrode active materials has since matured to the extent that vacuum thermal evaporation now has merit. Cost-competitive thermal evaporation requires an electrode application-specific web coating system design and operating method. The optimal prelithiation process for compensating for active lithium loss involves reactive lithium ions alloying with the graphite, silicon, and other anode constituents to compensate for lithium consumed by SEI formation. The optimal production worthy manufacturing method involves web processing anode substrates over one meter wide and thousands of meters long at web speeds around forty meters per minute or faster.

Web handling systems are not capable of double-sided coating let alone safe lithium thermal evaporation. The need therefore exists for a vacuum thermal evaporation lithiation system and method that can meet volume LIB manufacturing objectives for device performance, yield, throughput, and cost.

Some implementations of the present disclosure include a multi-zone heated diffuser or showerhead for single or double-sided continuous roll-to-roll or batch coating of continuous flexible substrates. Currently available techniques for lithium deposition involve placid pools of liquid lithium heated to a moderate temperature (e.g., 600 degrees Celsius). These designs are prone to splash defects, low throughput, and low lithium utilization. Implementations of the present disclosure include a close couple diffuser or showerhead designed to reduce splash defects, increase throughput, and improve lithium utilization. Flowing lithium vapor through a heated diffuser plenum reduces splash defects; utilizing a source crucible that is capable of evaporation near the boiling point of lithium (1340 degrees Celsius) improves throughput; and distributing vapor over a face area confining a slim process volume improves utilization. In some implementations, the manufacturing method includes system operation of pressurized argon and freezing valves to minimize source contamination with nitrogen, oxygen, and other contaminants.

Thermal evaporation is a physical vapor deposition (PVD) method where a heated source is used to produce vapor that condenses onto a substrate. Various vapor sources exist for thermal evaporation onto polymer and metal webs. The common principal in source design is physical separation between the material reservoir and deposition volumes. The purpose of segregating these volumes is to maintain high upstream pressure where the vapor can collect and physical properties (e.g., temperature, pressure, and concentration) equilibrate before being distributed and flowing into the deposition volume.

In one implementation of the present disclosure which can be combined with other implementations, nozzles, discharge openings, and/or slots can be used to separate the high-pressure reservoir volume from the deposition volume. These vapor flow restricting elements can be sized and positioned to control substrate deposition uniformity. Furthermore, multiple sources operating at different temperatures or containing different materials at different relative positions or with different restricting elements can be used to modulate deposition uniformity and composition.

Controlling the vapor temperature along the flow path from the material in the reservoir, through the restricting elements, into the deposition volume, and onto the web helps improve thermal evaporation coating quality and throughput.

Nozzles, slots, and other constricting elements can be optimized to a specific material and process conditions so that the vapor cools due to adiabatic expansion into the lower pressure vacuum deposition environment.

Adiabatic expansion and cooling helps the vaporized material stick to the web rather than bounce off. Cooling can be maximized by mixing pressurized gas in the material reservoir to raise the pressure or by increasing the vapor resistance in the constricting elements. That said, excessive cooling could lead to clogs due to material condensation; hence, the constricting elements and processing parameters are optimized for specific materials and web applications.

In one implementation of the present disclosure which can be combined with other implementations, the material reservoir volume is substantially smaller than the deposition volume, which simplifies the complexity of the heating system and can reduce direct radiation thermal load onto the web material. Minimizing excess stray radiation from the material reservoir (via line of sight through the restrictive elements) helps to reduce the heat load onto the web. Excess web heat load can cause vaporized material to bounce off the web rather than to stick.

Thermal evaporation sources typically include a hot shroud. A hot shroud is used so that the material that has bounced off the cool substrate will then hit a hot surface where the sticking coefficient will be low and it will bounce off the hot surface and thus have a second chance at sticking to the substrate.

In addition to the hot shroud, another common source design is minimizing the deposition volume and more specifically, the surface area of the low-pressure zone adjacent to the web. It is common practice to arrange the deposition exit nozzles at any angle so it is possible to spread out the deposition around the deposition drum. Because of the enclosed nature of the source it is possible to reduce the deposition losses to very small amounts giving very high, >99%, material utilization. In practice, however, specific applications require careful attention to materials, filling, pumping, and insulation schemes to facilitate continuous web coating over thousands of meters.

Implementations of the present disclosure include a thermal evaporation source suitable for volume electrode prelithiation. The thermal evaporation source complies with the aforementioned design approach at a facile level but has several features that enable volume substrate processing.

### Close Couple Diffuser Nozzle Design for Lithium Depletion and Adiabatic Gas Cooling

Gas showerheads for semiconductor wafer processing typically include multiple flow zones to compensate for radial precursor depletion. It has been observed that this depletion effect due to material loss as it is deposited on the wafer—can be useful for web processing given relative motion of the web relative to the showerhead; the web can be coated without the hot shroud by limiting the amount of lithium vapor mass flow and leveraging depletion in the machine direction.

In one implementation of the present disclosure which can be combined with other implementations, the deposition volume is minimized and defined to conform to the web that can travel over a cylindrical cooling drum, a planar cooling plate, or be free span. Features can include the relative nozzle diameters, aspect ratio, process spacing, and inlet location relative to the pumping outlet.

In one implementation of the present disclosure which can be combined with other implementations, the close couple diffuser includes counterbore features at the nozzle outlets. These nozzle counterbore features include adiabatic gas cooling as the lithium vapor expands into the deposition volume. Not to be bound by theory but it is believed that adiabatic gas cooling helps the lithium clusters stick to the substrate—as opposed to other source designs that have less mass flux and therefore have nozzle designs intended to prevent this gas cooling effect (in order to minimize nozzle clogging).

Since the close couple diffuser is designed to leverage vapor depletion heated shrouds are not needed. This is a marked improvement to current lithium thermal evaporation systems, which require time for heated shroud services to equilibrate on startup, time for heated shrouds to cool off after coating is complete, have lower utilization due to parasitic deposition, and higher operating costs due to heated shroud cleaning expense.

In one implementation of the present disclosure which can be combined with other implementations, the close couple diffuser is fabricated from a monolithic plate. Gas diffusers are typically manufactured from welded tube assemblies, which are challenging to manufacture for web widths greater than one meter. Fabricating the close couple diffuser using subtractive fabrication techniques, for example, CNC machining, beginning with a monolithic plate helps maintain nozzle placement dimensional control and can be less expensive than an equivalent welded assembly that often requires complex tooling and inert electron beam welding. Fabrication from a monolithic plate is specifically beneficial for LIB prelithiation because lithium-compatible alloys such as pure iron can be used. Pure iron does not alloy with lithium and is thus not susceptible to liquid metal cracking observed with other metals. Fabrication from a monolithic plate is also beneficial for producing ceramic close couple diffusers. Some ceramics such as graphite are compatible with lithium and can be used when a high emissivity surface, higher thermal conductivity, or specific wetting properties are required.

Manufacture from a single plate billet also simplifies mechanical support to compensate for thermal expansion. Webs wider than one meter require wider vapor sources. Manufacture from a single plate avoids the complexity of weldment distortion during fabrication and distortion during use. The plate is simpler to manufacture and heat to elevated processing temperatures. It can be centered on the web and allow thermal expansion in the transverse direction.

In summary, some implementations of the close couple diffuser described herein include a monolithic plate substantially designed to conform to the web (following a cylindrical or planar surface). The monolithic plate has a plurality of flow and temperature optimized nozzles to facilitate lithium vapor depletion in the machine and transverse directions of a web substrate.

### Temperature Controlled Diffuser Surfaces to Minimize Sticking

Vapor source nozzles can be designed so vapor jets toward and sticks to the substrate. In one implementation of the present disclosure which can be combined with other implementations, the nozzles of the close couple diffuser described herein are designed in this fashion. In order to improve machine capability to process thousands of meters before requiring service due to parasitic deposition, the close couple diffuser can be designed to obviate the need for hot shields by being equipped with multi-zone temperature control over the diffuser area.

In one implementation of the present disclosure which can be combined with other implementations, the close couple diffuser includes multi-zone temperature control. Slight variations in temperature up to ten degrees can cause runaway lithium condensation. Multi-zone temperature control over the diffuser area helps provide temperature uniformity when processing webs having widths greater than one meter. Multi-zone temperature control also helps minimizes wrinkles, which can cause prelithiation nonuniformity.

Vapor sources typically use thermocouples and nichrome or graphite heaters with one temperature zone per source. In one implementation of the present disclosure which can be combined with other implementations, the close couple diffuser has separate heating zones in both the machine and transverse directions. Each heating zone can be equipped with a non-contact control pyrometer or offset to a temperature calibrated control pyrometer.

### Flash Evaporation Crucible to Maximize Tool Uptime

In one implementation of the present disclosure which can be combined with other implementations, an evaporation system includes a close couple diffuser fluidly coupled with an evaporation source. The evaporation source includes a crucible, which can be heated. Rapid cooling of the vapor source is desirable for production-acceptable mean-time-to-repair (“MTTR”). Rapidly raising the chamber pressure by introducing an inert gas such as argon is one way to stop evaporation. Circulating an inert cooling fluid such as argon or oil to remove heat from the crucible is another way to stop evaporation. In one implementation of the present disclosure which can be combined with other implementations, the crucible has a low thermal mass and integral cooling system.

Some lithium thermal evaporation platforms begin web coating with a crucible filled with molten lithium, which is consumed throughout the production run. One disadvantage of this approach is that the entire crucible thermal mass is large and requires hours to cool and solidify. Not to be bound by theory but it is believed that a safer and more reliable approach is to minimize the volume of molten lithium inside the material reservoir to enable rapid cooling of the vapor source if needed. Electromagnetic pumps or pressurized vessels can be used to supply molten lithium from a remote reservoir into the vapor source. In one implementation of the present disclosure which can be combined with other implementations, the material reservoir volume of the crucible is minimized and the crucible can be operated as a flash evaporator.

Lithium boils below 1340 degrees Celsius in vacuum. Not to be bound by theory but the inventors believe flash evaporation in a crucible designed to heat above 1000 degrees Celsius provides higher lithium vapor pressure than alternative platforms with molten lithium pools serving as the source. In one implementation of the present disclosure which can be combined with other implementations, the close couple diffuser has a high surface area low mass crucible designed to operate above 1000 degrees Celsius so that molten lithium can flash evaporate immediately upon addition via the remote delivery system.

Flash evaporation enables intermittent coating without masking. In one example, intermittent coating involves a “step-and-grow” process, where rotation of the coating drum is stopped so the web located between the evaporator and the coating drum is stationary, and vapor condenses on the web until a final thickness of the coating is achieved. Next, the coating drum advances the web a fixed length that defines the uncoated intermittent distance between coated areas to position the uncoated web between the evaporator and the coating drum before stopping rotation, and vapor condenses until a final thickness of the coating is achieved. The cycle repeats to produce a continuous web with areas corresponding to the evaporator plate face area, spaced evenly apart.

### Operation in any Vertical or Horizontal Attitude for Maximum Utilization

The flash evaporation scheme allows the close couple diffuser to be installed in orientations that typical vapor sources cannot achieve. Vapor sources with liquid filled crucibles are orientation limited; elbows and other vapor-directing channels are required to maintain a horizontal liquid free surface. The ability to flash evaporate and orient the inventive vapor source at any angle is useful for optimizing equipment design. Specifically, the vapor source need not be installed below the cooling drum and parasitic surfaces such as elbows and other vapor-directing channels can be removed. In theory the inventive vapor source could be installed anywhere on the cooling drum or cooling plate surface; in practice a certain circumferential distance is typically used to cool the web prior to deposition so the principal benefit is overall greater circumferential utilization.

Operation in any vertical or horizontal attitude also facilitates use as a common source for cooling drum, cooling plate, and free span configurations. Liquid filled crucibles with pools of molten material that are limited to horizontal configurations are useful only under cooling drums.

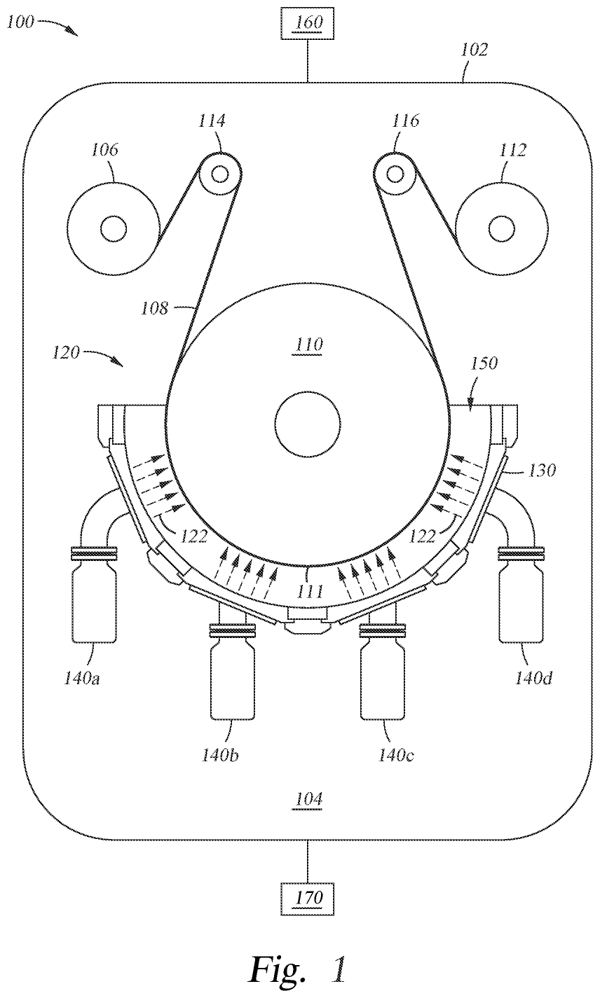

FIG. 1 illustrates a schematic side view of an evaporation system 100 having an evaporation assembly 120 according to one or more implementations of the present disclosure. The evaporation system 100 can be a roll-to-roll system adapted for depositing coatings on web materials, for example, for depositing metal containing film stacks according to the implementations described herein. In one example, the evaporation system 100 can be used for manufacturing energy storage devices, and particularly for film stacks for lithium-containing anodes. The evaporation system 100 includes a chamber body 102 that defines a common processing environment 104 in which some or all of the processing actions for depositing coatings on web materials can be performed. In one example, the common processing environment 104 is operable as a vacuum environment. In another example, the common processing environment 104 is operable as an inert gas environment. In some examples, the common processing environment 104 can be maintained at a process pressure of 1×10⁻³ mbar or below, for example, 1×10⁻⁴ mbar or below.

The evaporation system 100 is constituted as a roll-to-roll system including an unwinding reel 106 for supplying a continuous flexible substrate 108 or web, a coating drum 110 over which the continuous flexible substrate 108 is processed, and a winding reel 112 for collecting the continuous flexible substrate 108 after processing. The coating drum 110 includes a deposition surface 111 over which the continuous flexible substrate 108 travels while material is deposited onto the continuous flexible substrate 108. The evaporation system 100 can further include one or more auxiliary transfer reels 114, 116 positioned between the unwinding reel 106, the coating drum 110, and the winding reel 112. According to one aspect, at least one of the one or more auxiliary transfer reels 114, 116, the unwinding reel 106, the coating drum 110, and the winding reel 112, can be driven and rotated, by a motor. In one example, the motor is a stepper motor. Although the unwinding reel 106, the coating drum 110, and the winding reel 112 are shown as positioned in the common processing environment 104, it should be understood that the unwinding reel 106 and the winding reel 112 can be positioned in separate chambers or modules, for example, at least one of the unwinding reel 106 can be positioned in an unwinding module, the coating drum 110 can be positioned in a processing module, and the winding reel 112 can be positioned in an unwinding module.

The unwinding reel 106, the coating drum 110, and the winding reel 112 can be individually temperature controlled. For example, the unwinding reel 106, the coating drum 110, and the winding reel 112 can be individually heated using an internal heat source positioned within each reel or an external heat source.

The evaporation assembly 120 includes a diffuser assembly 130 fluidly coupled with one or more evaporation sources 140a-140d (collectively 140). The one or more evaporation sources 140 are removable from the diffuser assembly 130. The diffuser assembly 130 is positioned to deliver evaporated material from the one or more evaporation sources 140 onto the continuous flexible substrate 108 as the continuous flexible substrate 108 travels over the deposition surface 111 of the coating drum 110.

A deposition volume 150 is defined in between the diffuser assembly 130 and the deposition surface 111 of the coating drum 110. In some implementations, the deposition volume 150 provides an isolated processing within the common processing environment 104 of the chamber body 102. The deposition volume 150 can be minimized and defined to conform to a web, for example, the continuous flexible substrate 108 that is wound on a cylindrical cooling drum, for example, the coating drum 110, a planar cooling plate, or free span.

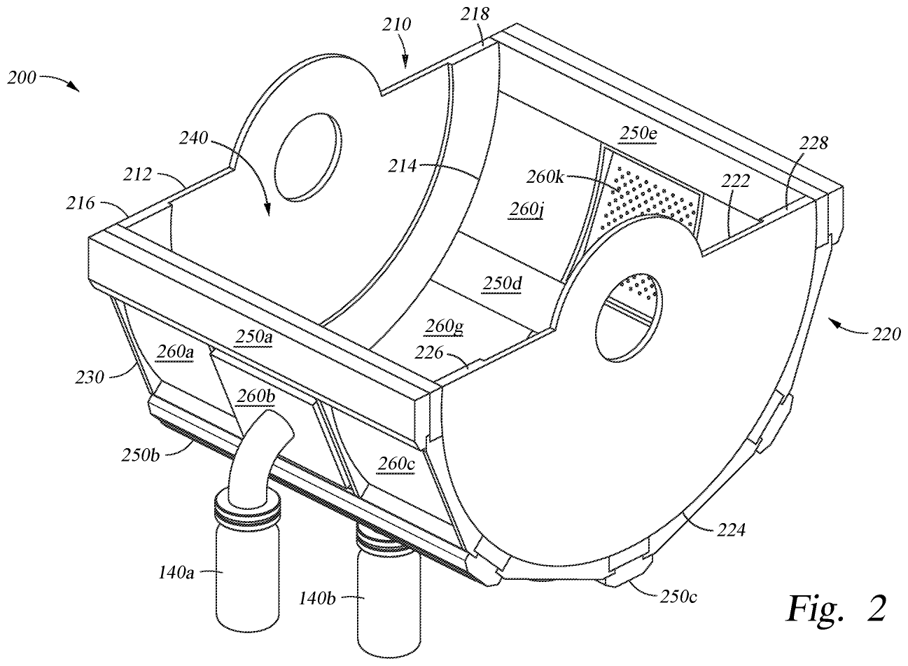

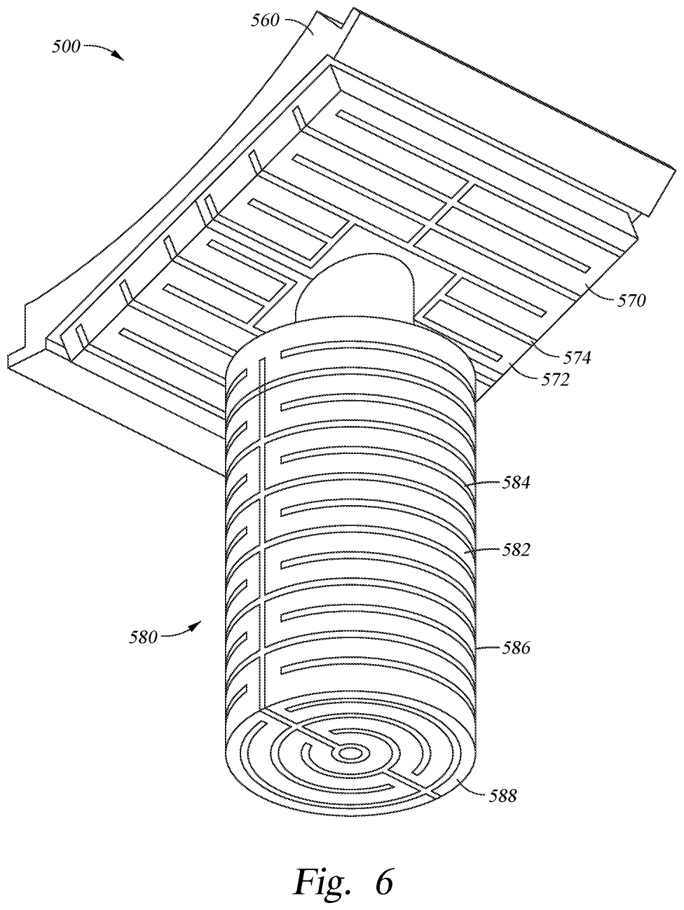

Both the diffuser assembly 130 and the evaporation source 140 will be described in greater detail with reference to FIGS. 2-6. The diffuser assembly 130 and evaporation source 140 are positioned to perform one or more processing operations to the continuous flexible substrate 108 or web of material. In one example, as depicted in FIG. 1, the diffuser assembly 130 is designed such that the one or more evaporation sources 140 are radially disposed about the coating drum 110. In addition, arrangements other than radial are contemplated. In one implementation, the one or more evaporation sources 140 include a lithium (Li) source. Further, the one or more evaporation sources 140 can also include an alloy of two or more metals. The material to be deposited can be provided in a crucible. The material to be deposited can be evaporated, for example, by thermal evaporation techniques.

In operation, the evaporation assembly 120 emits a plume of evaporated material 122, which is drawn to the continuous flexible substrate 108 where a film of deposited material is formed on the continuous flexible substrate 108.

In addition, although four evaporation sources 140a-140d are shown in FIG. 1, it should be understood that any number of suitable evaporation sources can be used. In addition, the evaporation system 100 can further include one or more additional deposition sources. For example, the one or more deposition sources as described herein include an electron beam source and additional sources, which can be selected from the group of CVD sources, PECVD sources, and various PVD sources. Exemplary PVD sources include sputtering sources, electron beam evaporation sources, and thermal evaporation sources. In addition, these additional deposition source can be positioned radially relative to the deposition surface 111 of the coating drum 110.

In one implementation of the present disclosure which can be combined with other implementations, the evaporation system 100 is configured to process both sides of the continuous flexible substrate 108. For example, additional evaporation sources similar to the evaporation sources 140 can be positioned to process the opposing side of the continuous flexible substrate 108. Although the evaporation system 100 is configured to process the continuous flexible substrate 108, which is horizontally oriented, the evaporation system 100 can be configured to process substrates positioned in different orientations, for example, the continuous flexible substrate 108 can be vertically oriented. In one implementation of the present disclosure which can be combined with other implementations, the continuous flexible substrate 108 is a flexible conductive substrate. In one implementation of the present disclosure which can be combined with other implementations, the continuous flexible substrate 108 includes a conductive substrate with one or more layers formed thereon. In one implementation of the present disclosure which can be combined with other implementations, the conductive substrate is a copper substrate.

The evaporation system 100 further includes a gas panel 160. The gas panel 160 uses one or more conduits (not shown) to deliver processing gases to the evaporation system 100. The gas panel 160 can include mass flow controllers and shut-off valves, to control gas pressure and flow rate for each individual gas supplied to the evaporation system 100. Examples of gases that can be delivered by the gas panel 160 include, but are not limited to, inert gases for pressure control (e.g., argon), etching chemistries including but not limited to diketones used for in-situ cleaning of the evaporation system 100, and deposition chemistries including but not limited to 1,1,1,2-Tetrafluoroethane or other hydrofluorocarbons and trimethyl aluminum, titanium tetrachloride, or other metal organic precursors used for in-situ tens of nanometer thick reactive lithium mixed conductor surface modification.

The evaporation system 100 further includes a system controller 170 operable to control various aspects of the evaporation system 100. The system controller 170 facilitates the control and automation of the evaporation system 100 and can include a central processing unit (CPU), memory, and support circuits (or I/O). Software instructions and data can be coded and stored within the memory for instructing the CPU. The system controller 170 can communicate with one or more of the components of evaporation system 100 via, for example, a system bus. A program (or computer instructions) readable by the system controller 170 determines which tasks are performable on a substrate. In some aspects, the program is software readable by the system controller 170, which can include code for monitoring chamber conditions, including independent temperature control of the one or more evaporation sources 140 and/or the various regions of the diffuser assembly 130. Although only a single system controller, the system controller 170 is shown, it should be appreciated that multiple system controllers can be used with the aspects described herein.

FIG. 2 illustrates a perspective view of a diffuser assembly 200 according to one or more implementations of the present disclosure. The diffuser assembly 200 can be the diffuser assembly 130 depicted in FIG. 1. The diffuser assembly 200 is sized to accommodate at least a portion of a coating drum, for example, the coating drum 110 shown in FIG. 1. The diffuser assembly 200 includes a first semicircular sidewall 210, a second semicircular sidewall 220 opposing the first semicircular sidewall 210, and a circumferential surface 230 extending between and coupled with the first semicircular sidewall 210 and the second semicircular sidewall 220. The first semicircular sidewall 210, the second semicircular sidewall 220, and the circumferential surface 230 define a volume 240 for accommodating a portion of a coating drum, for example, the coating drum 110 shown in FIG. 1.

The first semicircular sidewall 210 has a top surface 212 and an arcuate surface 214 extending from a first end 216 of the top surface 212 to a second end 218 of the top surface 212. In one example, the top surface 212 is a flat surface. The second semicircular sidewall 220 has a top surface 222 and an arcuate surface 224 extending from a first end 226 of the top surface 222 to a second end 228 of the top surface 222. In one example, the top surface 222 is a flat surface.

The circumferential surface 230 is defined by a plurality of linear rails 250a-250e (collectively 250) or linear brackets and a plurality of plates 260a-2601 (collectively 260). The plurality of plates 260 are supported by adjacent linear rails 250 to define the circumferential surface 230. Each linear rail of the plurality of linear rails 250 extends from the arcuate surface 214 of the first semicircular sidewall 210 to the arcuate surface 224 of the second semicircular sidewall 220. A first end of each linear rail of the plurality of linear rails 250 is secured to the first semicircular sidewall 210 and a second end of each linear rail of the plurality of linear rails 250 is secured to the second semicircular sidewall 220. Each linear rail 250 is parallel to an adjacent linear rail 250. For example, linear rail 250a is parallel to linear rail 250b.

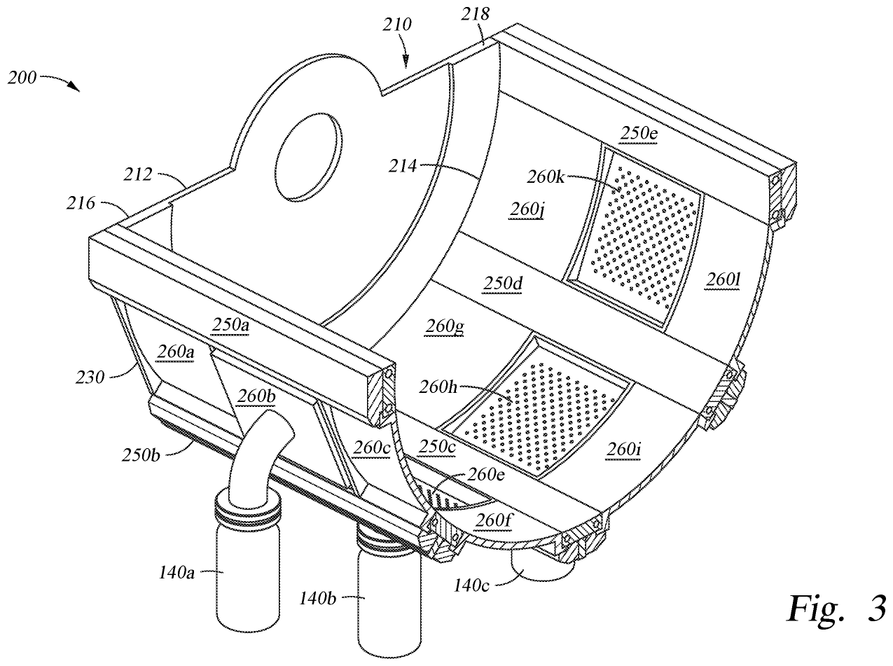

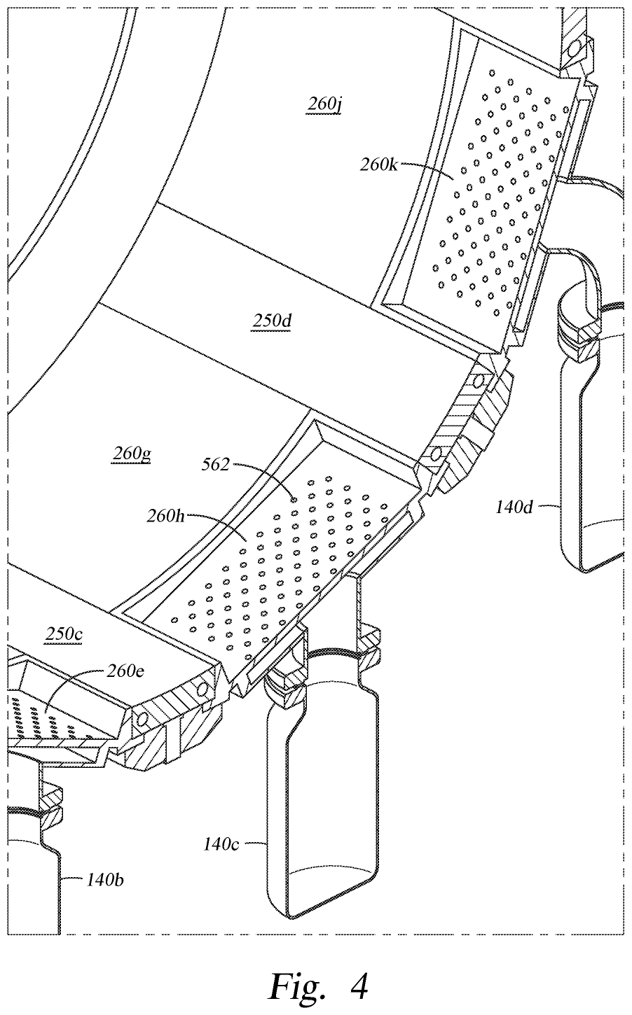

FIG. 3 illustrates a perspective view of the diffuser assembly 200 of FIG. 2 according to one or more implementations of the present disclosure. FIG. 4 illustrates an enlarged perspective view of a portion of the diffuser assembly 200 of FIG. 3 according to one or more implementations of the present disclosure. FIG. 3 depicts the diffuser assembly 200 with the second semicircular sidewall 220 removed. The diffuser assembly 200 includes a plurality of plates 260a-2601 (collectively 260). A back surface of each of the plurality of plates 260 define the circumferential surface 230. The diffuser assembly 200 includes twelve plates 260a-2601. Although twelve plates 260a-2601 (note 260d is not visible in this view) are shown in FIG. 3, any suitable number of plates 260 can be used depending on the desired pattern of deposited material or coating. The plate 260d is adjacent to the plate 260e. The plates 260 are interchangeable such that any number or combination of diffuser plates, solid plates (e.g., shields), or combinations thereof can be used. The positioning of the diffuser plates and solid plates determines the pattern of deposited material or coating. For example, in the embodiment of FIG. 3, plates 260a, 260c, 260d, 260f, 260g, 260i, 260j, and 260l are solid plates and plates 260b, 260e, 260h, and 260k are diffuser plates. The configuration of solid plates and diffuser plates depicted in FIG. 3 would deposit a coating along the center of the web while leaving the edges uncoated.

The plates 260a-2601 are divided into four sets of three plates. For example, plates 260a, 260b, 260c are supported by adjacent linear rails 250a and 250b; plates 260d, 260e, and 260f are supported by adjacent linear rails 250b and 250c; plates 260g, 260h, and 260i are supported by adjacent linear rails 250c and 250d; and plates 260j, 260k, and 260l are supported by adjacent linear rails 250d and 250e. The plates 260 are attached to the linear rails 250. The plates 260 can be slidably attached to the linear rails 250. Although five linear rails 250a-250e are shown in FIGS. 2 and 3, the diffuser assembly 200 can include two or more linear rails 250. The number of linear rails 250 can be determined by the number of plates 260 used.

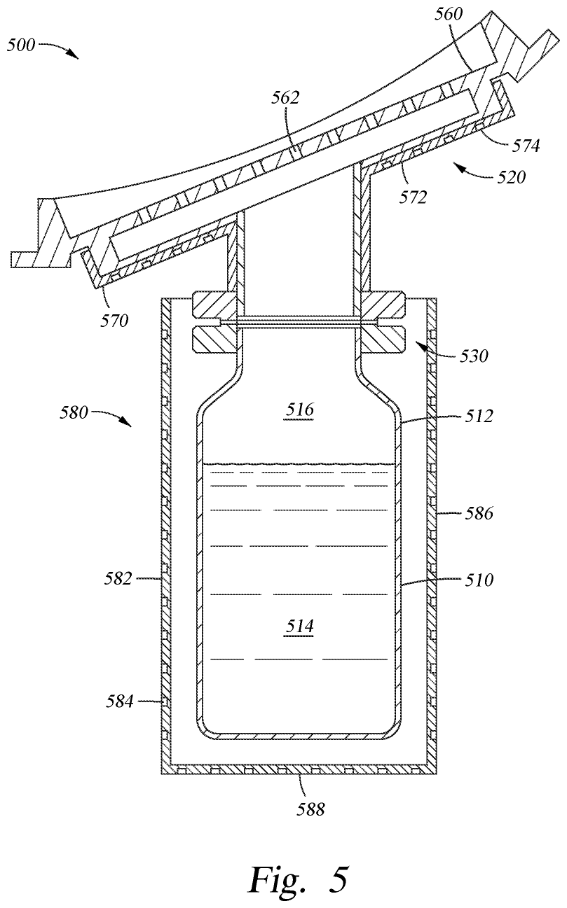

FIG. 5 illustrates a schematic cross-sectional view of a thermal evaporator 500 according to one or more implementations of the present disclosure. The thermal evaporator 500 includes a crucible 510 or evaporation source coupled with an evaporator body 520. The evaporator body 520 is operable to deliver evaporated material for deposition through a diffuser plate 560. The crucible 510 can be fluidly coupled with the evaporator body 520 via a flange 530. The crucible 510 is removably and adjustably positioned relative to the flange 530. Thus, the crucible 510 can be removed from the evaporator body 520 via the flange 530.

In one embodiment which can be combined with other embodiments, the diffuser plate 560 is a monolithic (e.g., weld-less) body. The diffuser plate 560 can be fabricated from iron (e.g., pure iron), graphite, stainless steel, or a combination thereof. The diffuser plate 560 includes a plurality of discharge openings 562 or nozzles through which the evaporated material travels. In one embodiment which can be combined with other embodiments, the plurality of discharge openings 562 are arranged and sized for controlled vapor depletion in the machine direction. This arrangement of the plurality of discharge openings 562 provides for high utilization without the use of hot shroud designs.

A heater plate 570 is positioned adjacent to and in thermal contact with the diffuser plate 560. The heater plate 570 can be a component of the diffuser plate 560 or a separate component. Energy from the heater plate 570 affects the diffuser plate 560 elevating the temperature of the diffuser plate 560. In one embodiment which can be combined with other embodiments, the heater plate 570 is a resistive graphite heater. In other embodiments, the heater plate 570 can include other materials such as aluminum, stainless steel or materials such as Inconel. The heater plate 570 can include a plurality of resistive graphite heating elements 574 with pyrometer plate temperature measurement and closed loop temperature controls for controlling the temperature of the diffuser plate 560. The heater plate 570 can further include one or more pyrometers for temperature measurement of the heater plate 570 and/or the diffuser plate 560 and closed loop temperature controls for controlling the temperature of the diffuser plate 560. For example, the pyrometer temperature measurement of the diffuser plate 560 can be transmitted to the system controller 170, which then adjusts the temperature of the heater plate 570 to achieve a desired temperature of the diffuser plate 560.

In one embodiment which can be combined with other embodiments, a body 572 of the heater plate 570 is made of graphite. In one embodiment which can be combined with other embodiments, the body 572 comprises substantially only graphite, meaning that the composition of the body 572 is greater than about 95% carbon on an atomic basis. In one embodiment which can be combined with other embodiments, the composition of the body 572 is greater than about 96%, 97%, 98%, 99%, 99.5%, or 99.9% carbon on an atomic mass basis.

The heater plate 570 includes one or more resistive heating element(s). The resistive heating element of some embodiments is a continuous section of material—which can be planar, round, or other shape—disposed within a recess of the body 572. In some embodiments, the resistive heater comprises wound bodies of metal wire. In one example, the heater plate 570 has two resistive heaters forming two zones, those skilled in the art will understand that there can be any number of zones or individual heating elements. In some embodiments, there are three resistive heaters forming three zones. In some embodiments, there are four resistive heaters forming four zones.

All or any of the resistive heating elements may be made from any suitable material known in the art. In some embodiments, the resistive heating element(s) has a coefficient of thermal expansion similar to those of the body 572. One example of a suitable material for the resistive heating elements includes pyrolytic graphite.

The crucible 510 includes a vessel 512 capable of holding a material 514 to be deposited. The vessel 512 can be a monolithic restricted orifice vessel 512. The vessel 512 defines an interior region 516. The interior region 516 is operable for holding a material 514 to be deposited. Examples of the material 514 include alkali metals (e.g., lithium and sodium), magnesium, zinc, cadmium, aluminum, gallium, indium, thallium, selenium, tin, lead, antimony, bismuth, tellurium, alkali earth metals, silver, or combinations thereof. In one example, the material includes lithium, selenium, or sodium.

The crucible 510 can be formed of a material having high-thermal conductivity, such as molybdenum, graphite, stainless steel, or boron nitride. In one example, the crucible 510 is composed of pyrolytic boron nitride. Pyrolytic boron nitride is generally inert, can withstand high temperatures, is generally clean and does not contribute undesirable impurities to the vacuum environment, is generally transparent to certain wavelengths of infrared radiation, and can be fabricated into complex shapes, for example. In one embodiment which can be combined with other embodiments, the crucible is designed for flash evaporation, for example, an attitude-independent crucible for flash evaporation.

In one embodiment which can be combined with other embodiments, the thermal evaporator 500 further includes a crucible heater 580. The crucible heater 580 surrounds the crucible 510 and is conformable to the crucible 510. The crucible heater 580 enables the thermal evaporator 500 to function as a flash evaporator. The crucible heater 580 can include an induction coil heater or a resistive graphite heating element. Energy from the crucible heater 580 affects the crucible 510 elevating the temperature of the crucible 510. In one embodiment which can be combined with other embodiments, the crucible heater 580 is a resistive graphite heater. In other embodiments, the crucible heater 580 can include other materials such as aluminum, stainless steel or materials such as Inconel. The crucible heater 580 can include a plurality of resistive graphite heating elements with pyrometer temperature measurement and closed loop temperature controls for controlling the temperature of the crucible 510. For example, the pyrometer temperature measurement can be transmitted to the system controller 170, which then adjusts the temperature of the crucible heater 580 to achieve a desired temperature of the crucible 510.

In one embodiment which can be combined with other embodiments, a body 582 of the crucible heater 580 is made of graphite. The body 582 includes a sidewall 586 and a bottom surface 588, which define an enclosure for accommodating the crucible 510. In one embodiment which can be combined with other embodiments, the body 582 comprises substantially only graphite, meaning that the composition of the body 582 is greater than about 95% carbon on an atomic basis. In one embodiment which can be combined with other embodiments, the composition of the body 582 is greater than about 96%, 97%, 98%, 99%, 99.5%, or 99.9% carbon on an atomic mass basis.

The crucible heater 580 includes one or more resistive heating element(s) 584. The resistive heating element of some embodiments is a continuous section of material—which can be planar, round, or other shape—disposed within a recess of the body 582. In some embodiments, the crucible heater 580 comprises wound bodies of metal wire. In one example, the heater plate 570 has two resistive heaters forming two zones, those skilled in the art will understand that there can be any number of zones or individual heating elements. In some embodiments, there are three resistive heaters forming three zones. In some embodiments, there are four resistive heaters forming four zones.

All or any of the resistive heating element(s) 584 can be made from any suitable material known in the art. In some embodiments, the resistive heating element(s) 584 has a coefficient of thermal expansion similar to those of the body 572. One example of a suitable material for the resistive heating element(s) 584 includes pyrolytic graphite.

### EMBODIMENTS LISTING

The present disclosure provides, among others, the following embodiments, each of which can be considered as optionally including any alternate embodiments:

Clause 1. A diffuser assembly, comprising:

a first semicircular sidewall having a first top surface and a first arcuate surface extending from a first end of the first top surface to a second end of the first top surface;

a second semicircular sidewall opposing the first semicircular sidewall and having a second top surface and a second arcuate surface extending from a first end of the second top surface to a second end of the second top surface;

a plurality of linear rails extending from the first arcuate surface of the first semicircular sidewall to the second arcuate surface of the second semicircular sidewall, wherein each linear rail is positioned parallel to an adjacent linear rail; and

a plurality of plates extending from a first linear rail to a second linear rail of the plurality of linear rails, wherein the plurality of plates define at least a portion of a circumferential surface extending from a first end of the first top surface to a second end of the first top surface and at least one of the plates is a first diffuser plate having a plurality of discharge openings for delivering an evaporated material.

Clause 2. The diffuser assembly of Clause 1, wherein the first semicircular sidewall, the second semicircular sidewall, and the circumferential surface define a volume sized to accommodate a portion of a coating drum.

Clause 3. The diffuser assembly of Clause 1 or Clause 2, wherein the plurality of plates are slidably attached to the first linear rail and the second linear rail.

Clause 4. The diffuser assembly of any one of Clauses 1-3, wherein each plate of the plurality of plates is operable for independent temperature control relative to the other plates of the plurality of plates.

Clause 5. The diffuser assembly of any one of Clauses 1-4, wherein the plurality of discharge openings are arranged and sized for controlled vapor depletion in a travel direction of a web material to be coated by the evaporated material.

Clause 6. The diffuser assembly of any one of Clauses 1-5, wherein the plurality of plates comprise:

a first solid plate positioned adjacent to the first semicircular sidewall and extending from the first linear rail to the second linear rail;

a second solid plate positioned adjacent to the second semicircular sidewall and extending from the first linear rail to the second linear rail; and

the first diffuser plate having the plurality of discharge openings operable to deliver the evaporated material and positioned in between the first solid plate and the second solid plate.

Clause 7. The diffuser assembly of any one of Clauses 1-6, wherein the plurality of plates comprise:

a second diffuser plate positioned adjacent to the first semicircular sidewall and extending from the first linear rail to the second linear rail;

a third diffuser plate positioned adjacent to the second semicircular sidewall and extending from the first linear rail to the second linear rail; and

the first diffuser plate positioned in between the second diffuser plate and the third diffuser plate.

Clause 8. The diffuser assembly of any one of Clauses 1-7, wherein the plurality of linear rails further comprises:

a third linear rail of the plurality of linear rails positioned adjacent to the first linear rail; and

a second plurality of plates extending from the second linear rail to the third linear rail, wherein the second plurality of plates define at least a portion of the circumferential surface and at least one of the plates of the second plurality of plates is a second diffuser plate having a plurality of discharge openings operable to deliver the evaporated material.

Clause 9. An evaporation assembly, comprising:

a diffuser assembly, comprising:
a first semicircular sidewall having a first top surface and a first arcuate surface extending from a first end of the first top surface to a second end of the first top surface;
a second semicircular sidewall opposing the first semicircular sidewall and having a second top surface and a second arcuate surface extending from a first end of the second top surface to a second end of the second top surface;
a plurality of linear rails extending from the first arcuate surface of the first semicircular sidewall to the second arcuate surface of the second semicircular sidewall, wherein each linear rail is positioned parallel to an adjacent linear rail; and
a plurality of plates extending from a first linear rail to a second linear rail of the plurality of linear rails, wherein the plurality of plates define at least a portion of a circumferential surface extending from a first end of the first top surface to a second end of the first top surface and at least one of the plates is a first diffuser plate having a plurality of discharge openings operable to deliver an evaporated material; and

a crucible fluidly coupled with the first diffuser plate and operable to hold a material to be evaporated.

Clause 10. The evaporation assembly of Clause 9, wherein the crucible is operable for flash evaporation.

Clause 11. The evaporation assembly of Clause 9 or Clause 10, wherein the first semicircular sidewall, the second semicircular sidewall, and the circumferential surface define a volume sized to accommodate a portion of a coating drum.

Clause 12. The evaporation assembly of any one of Clauses 9-11, wherein the plurality of plates are slidably attached to the first linear rail and the second linear rail.

Clause 13. The evaporation assembly of any one of Clauses 9-12, wherein each plate of the plurality of plates is configured for independent temperature control relative to the other plates of the plurality of plates.

Clause 14. The evaporation assembly of any one of Clauses 9-13, wherein the plurality of discharge openings are arranged and sized for controlled vapor depletion in a travel direction of a web material to be coated by the evaporated material.

Clause 15. The evaporation assembly of any one of Clauses 9-14, wherein the plurality of plates comprise:

a first solid plate positioned adjacent to the first semicircular sidewall and extending from the first linear rail to the second linear rail;

a second solid plate positioned adjacent to the second semicircular sidewall and extending from the first linear rail to the second linear rail; and

the first diffuser plate having the plurality of discharge openings operable to deliver the evaporated material positioned in between the first solid plate and the second solid plate.

Clause 16. The evaporation assembly of any one of Clauses 9-15, wherein the plurality of plates comprise:

a second diffuser plate positioned adjacent to the first semicircular sidewall and extending from the first linear rail to the second linear rail;

a third diffuser plate positioned adjacent to the second semicircular sidewall and extending from the first linear rail to the second linear rail; and

the first diffuser plate positioned in between the second diffuser plate and the third diffuser plate.

Clause 17. The evaporation assembly of any one of Clauses 9-16, wherein the plurality of linear rails further comprises:

a third linear rail of the plurality of linear rails positioned adjacent to the first linear rail; and

a second plurality of plates extending from the second linear rail to the third linear rail, wherein the second plurality of plates define at least a portion of the circumferential surface and at least one of the plates of the second plurality of plates is a second diffuser plate having a plurality of discharge openings operable to deliver the evaporated material.

Clause 18. A system for reactive deposition, comprising:

a coating drum having a deposition surface over which a continuous flexible substrate travels while evaporated material is deposited onto the continuous flexible substrate;

a diffuser assembly, comprising:
a first semicircular sidewall having a first top surface and a first arcuate surface extending from a first end of the first top surface to a second end of the first top surface;
a second semicircular sidewall opposing the first semicircular sidewall and having a second top surface and a second arcuate surface extending from a first end of the second top surface to a second end of the second top surface;
a plurality of linear rails extending from the first arcuate surface of the first semicircular sidewall to the second arcuate surface of the second semicircular sidewall, wherein each linear rail is positioned parallel to an adjacent linear rail; and
a plurality of plates extending from a first linear rail to a second linear rail of the plurality of linear rails, wherein the plurality of plates define at least a portion of a circumferential surface extending from a first end of the first top surface to a second end of the first top surface, wherein at least one of the plates is a first diffuser plate having a plurality of discharge openings operable to deliver the evaporated material to the continuous flexible substrate, and wherein the first semicircular sidewall, the second semicircular sidewall, and the circumferential surface define a volume sized to accommodate a portion of the coating drum; and

a crucible fluidly coupled with the first diffuser plate and operable to hold a material, which is heated to form the evaporated material.

Clause 19. The system of Clause 18, wherein the plurality of plates are slidably attached to the first linear rail and the second linear rail.

Clause 20. The system of Clause 18 or Clause 19, wherein each plate of the plurality of plates is configured for independent temperature control relative to the other plates of the plurality of plates.

Clause 21. The system of any one of Clauses 18-20, wherein the plurality of discharge openings are arranged and sized for controlled vapor depletion in a travel direction of a web material to be coated by the evaporated material.

Clause 22. The system of any one of Clauses 18-21, wherein the plurality of plates comprise:

a first solid plate positioned adjacent to the first semicircular sidewall and extending from the first linear rail to the second linear rail;

a second solid plate positioned adjacent to the second semicircular sidewall and extending from the first linear rail to the second linear rail; and

the first diffuser plate having the plurality of discharge openings operable to deliver the evaporated material positioned in between the first solid plate and the second solid plate.

Clause 23. The system of any one of Clauses 18-22, wherein the plurality of plates comprise:

a second diffuser plate positioned adjacent to the first semicircular sidewall and extending from the first linear rail to the second linear rail;

a third diffuser plate positioned adjacent to the second semicircular sidewall and extending from the first linear rail to the second linear rail; and

the first diffuser plate positioned in between the second diffuser plate and the third diffuser plate.

Clause 24. The system of any one of Clauses 18-23, wherein the plurality of linear rails further comprises:

a third linear rail of the plurality of linear rails positioned adjacent to the first linear rail; and

a second plurality of plates extending from the second linear rail to the third linear rail, wherein the second plurality of plates define at least a portion of the circumferential surface and at least one of the plates of the second plurality of plates is a second diffuser plate having a plurality of discharge openings operable to deliver the evaporated material.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further implementations of the disclosure may be devised without departing from the basic scope thereof, and the scope thereof is determined by the claims that follow.

What is claimed is:

1. A diffuser assembly, comprising:
a first semicircular sidewall having a first top surface and a first arcuate surface extending from a first end of the first top surface to a second end of the first top surface;
a second semicircular sidewall opposing the first semicircular sidewall and having a second top surface and a second arcuate surface extending from a first end of the second top surface to a second end of the second top surface;
a plurality of linear rails extending from the first arcuate surface of the first semicircular sidewall to the second arcuate surface of the second semicircular sidewall, wherein each linear rail is positioned parallel to an adjacent linear rail; and
a plurality of plates extending from a first linear rail to a second linear rail of the plurality of linear rails, wherein the plurality of plates define at least a portion of a circumferential surface extending from a first end of the first top surface to a second end of the first top surface and at least one of the plates is a first diffuser plate having a plurality of discharge openings for delivering an evaporated material.

2. The diffuser assembly of claim 1, wherein:
the first semicircular sidewall, the second semicircular sidewall, and the circumferential surface define a volume sized to accommodate a portion of a coating drum;
the plurality of plates are slidably attached to the first linear rail and the second linear rail; or
a combination thereof.

3. The diffuser assembly of claim 1, wherein each plate of the plurality of plates is operable for independent temperature control relative to the other plates of the plurality of plates.

4. The diffuser assembly of claim 1, wherein the plurality of discharge openings are arranged and sized for controlled vapor depletion in a travel direction of a web material to be coated by the evaporated material.

5. The diffuser assembly of claim 1, wherein the plurality of plates comprise:
a first solid plate positioned adjacent to the first semicircular sidewall and extending from the first linear rail to the second linear rail;
a second solid plate positioned adjacent to the second semicircular sidewall and extending from the first linear rail to the second linear rail; and
the first diffuser plate having the plurality of discharge openings operable to deliver the evaporated material and positioned in between the first solid plate and the second solid plate.

6. The diffuser assembly of claim 1, wherein the plurality of plates comprise:
a second diffuser plate positioned adjacent to the first semicircular sidewall and extending from the first linear rail to the second linear rail;
a third diffuser plate positioned adjacent to the second semicircular sidewall and extending from the first linear rail to the second linear rail; and
the first diffuser plate positioned in between the second diffuser plate and the third diffuser plate.

7. The diffuser assembly of claim 1, wherein the plurality of linear rails further comprises:
a third linear rail of the plurality of linear rails positioned adjacent to the first linear rail; and
a second plurality of plates extending from the second linear rail to the third linear rail, wherein the second plurality of plates define at least a portion of the circumferential surface and at least one of the plates of the second plurality of plates is a second diffuser plate having a plurality of discharge openings operable to deliver the evaporated material.

8. An evaporation assembly, comprising:
a diffuser assembly, comprising:
a first semicircular sidewall having a first top surface and a first arcuate surface extending from a first end of the first top surface to a second end of the first top surface;
a second semicircular sidewall opposing the first semicircular sidewall and having a second top surface and a second arcuate surface extending from a first end of the second top surface to a second end of the second top surface;
a plurality of linear rails extending from the first arcuate surface of the first semicircular sidewall to the second arcuate surface of the second semicircular sidewall, wherein each linear rail is positioned parallel to an adjacent linear rail; and
a plurality of plates extending from a first linear rail to a second linear rail of the plurality of linear rails, wherein the plurality of plates define at least a portion of a circumferential surface extending from a first end of the first top surface to a second end of the first top surface and at least one of the plates is a first diffuser plate having a plurality of discharge openings operable to deliver an evaporated material; and
a crucible fluidly coupled with the first diffuser plate and operable to hold a material to be evaporated.

9. The evaporation assembly of claim 8, wherein the crucible is operable for flash evaporation.

10. The evaporation assembly of claim 8, wherein the first semicircular sidewall, the second semicircular sidewall, and the circumferential surface define a volume sized to accommodate a portion of a coating drum.

11. The evaporation assembly of claim 8, wherein the plurality of plates are slidably attached to the first linear rail and the second linear rail.

12. The evaporation assembly of claim 8, wherein:
each plate of the plurality of plates is configured for independent temperature control relative to the other plates of the plurality of plates;
the plurality of discharge openings are arranged and sized for controlled vapor depletion in a travel direction of a web material to be coated by the evaporated material; or
a combination thereof.

13. The evaporation assembly of claim 8, wherein the plurality of plates comprise:
a first solid plate positioned adjacent to the first semicircular sidewall and extending from the first linear rail to the second linear rail;
a second solid plate positioned adjacent to the second semicircular sidewall and extending from the first linear rail to the second linear rail; and
the first diffuser plate having the plurality of discharge openings operable to deliver the evaporated material positioned in between the first solid plate and the second solid plate.

14. The evaporation assembly of claim 8, wherein the plurality of plates comprise:
a second diffuser plate positioned adjacent to the first semicircular sidewall and extending from the first linear rail to the second linear rail;
a third diffuser plate positioned adjacent to the second semicircular sidewall and extending from the first linear rail to the second linear rail; and
the first diffuser plate positioned in between the second diffuser plate and the third diffuser plate.

15. The evaporation assembly of claim 8, wherein the plurality of linear rails further comprises:
a third linear rail of the plurality of linear rails positioned adjacent to the first linear rail; and
a second plurality of plates extending from the second linear rail to the third linear rail, wherein the second plurality of plates define at least a portion of the circumferential surface and at least one of the plates of the second plurality of plates is a second diffuser plate having a plurality of discharge openings operable to deliver the evaporated material.

16. A system for reactive deposition, comprising:
a coating drum having a deposition surface over which a continuous flexible substrate travels while evaporated material is deposited onto the continuous flexible substrate;
a diffuser assembly, comprising:
a first semicircular sidewall having a first top surface and a first arcuate surface extending from a first end of the first top surface to a second end of the first top surface;
a second semicircular sidewall opposing the first semicircular sidewall and having a second top surface and a second arcuate surface extending from a first end of the second top surface to a second end of the second top surface;
a plurality of linear rails extending from the first arcuate surface of the first semicircular sidewall to the second arcuate surface of the second semicircular sidewall, wherein each linear rail is positioned parallel to an adjacent linear rail; and
a plurality of plates extending from a first linear rail to a second linear rail of the plurality of linear rails, wherein the plurality of plates define at least a portion of a circumferential surface extending from a first end of the first top surface to a second end of the first top surface, wherein at least one of the plates is a first diffuser plate having a plurality of discharge openings operable to deliver the evaporated material to the continuous flexible substrate, and wherein the first semicircular sidewall, the second semicircular sidewall, and the circumferential surface define a volume sized to accommodate a portion of the coating drum; and
a crucible fluidly coupled with the first diffuser plate and operable to hold a material, which is heated to form the evaporated material.

17. The system of claim 16, wherein:
the plurality of plates are slidably attached to the first linear rail and the second linear rail;
each plate of the plurality of plates is configured for independent temperature control relative to the other plates of the plurality of plates;
the plurality of discharge openings are arranged and sized for controlled vapor depletion in a travel direction of a web material to be coated by the evaporated material; or
combinations thereof.

18. The system of claim 16, wherein the plurality of plates comprise:
a first solid plate positioned adjacent to the first semicircular sidewall and extending from the first linear rail to the second linear rail;
a second solid plate positioned adjacent to the second semicircular sidewall and extending from the first linear rail to the second linear rail; and
the first diffuser plate having the plurality of discharge openings operable to deliver the evaporated material positioned in between the first solid plate and the second solid plate.

19. The system of claim 18, wherein the plurality of plates comprise:
a second diffuser plate positioned adjacent to the first semicircular sidewall and extending from the first linear rail to the second linear rail;
a third diffuser plate positioned adjacent to the second semicircular sidewall and extending from the first linear rail to the second linear rail; and
the first diffuser plate positioned in between the second diffuser plate and the third diffuser plate.

20. The system of claim 18, wherein the plurality of linear rails further comprises:
a third linear rail of the plurality of linear rails positioned adjacent to the first linear rail; and
a second plurality of plates extending from the second linear rail to the third linear rail, wherein the second plurality of plates define at least a portion of the circumferential surface and at least one of the plates of the second plurality of plates is a second diffuser plate having a plurality of discharge openings operable to deliver the evaporated material.
